(19) United States
(12) Patent Application Publication
(10) Pub. No.: US 2011/0088846 A1
(43) Pub. Date: Apr. 21, 2011

(54) PLASMA SOURCE

(75) Inventor: Young Kim, Cupertino, CA (US)

(73) Assignee: NEST CORP., Suwon-si, Gyeonggi-do (KR)

(21) Appl. No.: 12/997,809

(22) PCT Filed: Jun. 10, 2009
(86) PCT No.: PCT/KR09/03107

§ 371 Date: Dec. 13, 2010

(30) Foreign Application Priority Data
Jun. 13, 2008 (KR) 10-2008-0055917

(51) Int. Cl. H01L 21/02; C23F 1/08; C23C 16/50

(52) U.S. Cl. 156/345.1; 118/723 R

(57) ABSTRACT

A plasma source is disclosed. The plasma source includes: a disc-shaped core; “m” number of hubs, “m” being a positive integer, each hub extending a certain length in a horizontal spiral from the core and the hubs being arranged rotationally symmetrical to each other; and main coils each, in a continuous extension from an end of each of the hubs, winding a/m times in a horizontal spiral followed by a certain length of radial extension, winding a/m times in another horizontal spiral followed by a certain length of radial extension, and continuing this sequence in multiple repeats, and wherein “a” and “m” are positive integers. Therefore, the present disclosure contributes to the uniformity of the process under plasma by inducing uniform magnetic and electric fields presented over all.

### CROSS-REFERENCE TO RELATED APPLICATION

This application claims the priority of Korean Patent Application No. 10-2008-0055917, filed on Jun. 13, 2008 in the KIPO (Korean Intellectual Property Office), the disclosure of which is incorporated herein in their entirety by reference. Further, this application is the National Phase application of International Application No. PCT/KR2009/003107, filed on Jun. 10, 2009, which designates the United States and was published in Korean. This application is hereby incorporated by reference in its entirety into the present application.

### TECHNICAL FIELD

The present disclosure relates to an apparatus for manufacturing semiconductors. More particularly, the present disclosure relates to a plasma source for forming plasma in a plasma chamber.

### BACKGROUND ART

The statements in this section merely provide background information related to the present disclosure and may not constitute prior art.

Techniques for manufacturing ultra large scale integrated circuit (ULSI) components have shown astonishing development for the last two decades. Realization of such ULSI productions has been backed by the semiconductor manufacturing facilities which can support the extreme processing requirements for the manufacturing processes. Of the facilities, a plasma chamber is gaining diverse applications including the deposition process beyond its typical operation in the etching process.

The plasma chamber is a semiconductor manufacturing facility which internally forms plasma for use in performing the etching, deposition, or other processes. Plasma chambers are classified into various types by the plasma generating sources including an electron cyclotron resonance (ECR) plasma source, a helicon-wave excited plasma (HWEP) source, a capacitively coupled plasma (CCP) source, an inductively coupled plasma (ICP) source, etc. Recently suggested was an adaptively coupled plasma (ACP) source which takes the advantages of both the capacitively coupled plasma source and the inductively coupled plasma source.

Referring to FIGS. 1 and 2, a plasma chamber 100 has an inner reaction space 104 defined into a predetermined volume by a chamber outer wall 102 and a dome 112. At a portion of reaction space 104, plasma 110 is formed under certain condition. Although the drawing is conveniently simplified that plasma chamber 100 is downwardly open at reaction space 104, plasma chamber 100 is actually isolated from atmosphere at its bottom and thus maintains vacuum internally. Disposed on the bottom of plasma chamber 100 is a wafer susceptor or electrostatic chuck 106, on which a semiconductor wafer 108 is seated for subsequent processing. Susceptor 106 is connected to an external RF bias power source 116. Although not shown in the drawings, inside susceptor 106, a heater may be disposed. On top of dome 112, there is a plasma source 200 externally arranged for generating plasma 110. As shown in FIG. 2, plasma source 200 comprises a plurality, for example, four of a first to fourth unit coils 131-134 and a bushing 120. Specifically, bushing 120 is centrally disposed and first to fourth unit coils 131-134 extend in spiral turns from bushing 120. The number of the illustrative four unit coils is arbitrary. Centrally disposed on bushing 120 is a vertical upstanding post 140. Post 140 is connected to a terminal of RF power source 114. The other terminal of RF power source 114 is grounded. The power from RF power source 114 is supplied through post 140 and bushing 120 to first to fourth unit coils 131-134, respectively. Such a conventional plasma coil source 200 has a circular construction extending from bushing 120 and surrounding the same. This circular construction forms an intensity of magnetic field as defined by equation 1 below.

$$\frac{\partial B}{\partial t} = - ∇ \times E \qquad Equation 1$$

In equation 1, B is magnetic flux density, ∇ is Del operator, E represents intensity of electric field.

This magnetic field formation under Maxwell equation applies to most plasma coil sources which entail radially diverging magnetic anomalies from their centers to the edges, resulting in difficulties in regulating the critical dimension (CD) and attaining the uniformity of etch rate between the centers and edges which is problematic.

Other problems associated with the conventional ACP source include restrictions in determining the minimum gap between coils and the number of coil turns in a design to prevent the micro-arcing from generating between the coils, difficulties in finding a proper process regime due to the susceptibility to electrical impedance reductions and inappropriate ratio of the ions to the free radicals, and the difficulty in the impedance matching.

In other words, the coil asymmetry of the conventional ACP source causes an asymmetry in either the induced magnetic field or the induced electric field, resulting in such a nonuniformity in the eventual processes.

### DISCLOSURE

### Technical Problem

Therefore, the present disclosure has been made for providing a plasma source having coils constructed to improve the process uniformity by symmetrizing the induced magnetic field as well as the induced electric field.

### Technical Solution

One aspect of the present disclosure provides a plasma source including: a disc-shaped core; ‘m’ number of hubs, ‘m’ being a positive integer, each hub extending a certain length in a horizontal spiral from the core and the hubs being arranged rotationally symmetrical to each other; and main coils each, in a continuous extension from an end of each of the hubs, winding a/m times in a horizontal spiral followed by a certain length of radial extension, winding a/m times in another horizontal spiral followed by a certain length of radial extension, and continuing this sequence in multiple repeats, and wherein “a” and “m” are positive integers.

The certain length of radial extension of the main coil may be made to become incremental or decremental as the number of windings of the main coil is increased, or it may remain the same regardless of the number of windings of the main coil.

### Advantageous Effects

According to an aspect of the plasma source, variations of the certain length of radial extension, spacing between the coils, and the coil counts and turns can change the characteristics of the process.

### DESCRIPTION OF DRAWINGS

FIG. 1 is a schematic diagram for showing a plasma including a conventional ACP source;

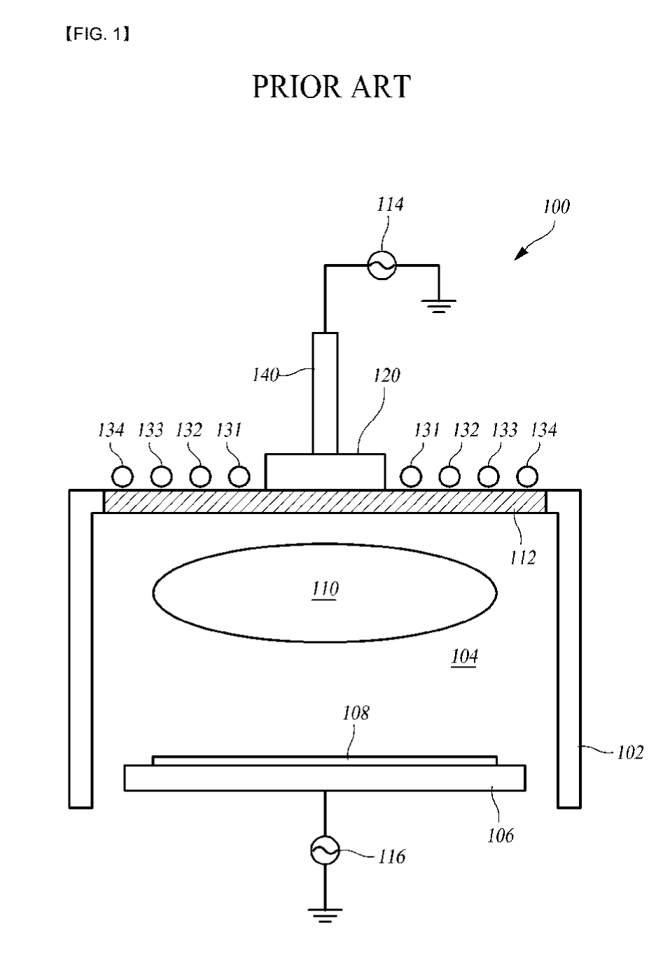

FIG. 2 is a plan view of the ACP source shown in FIG. 1;

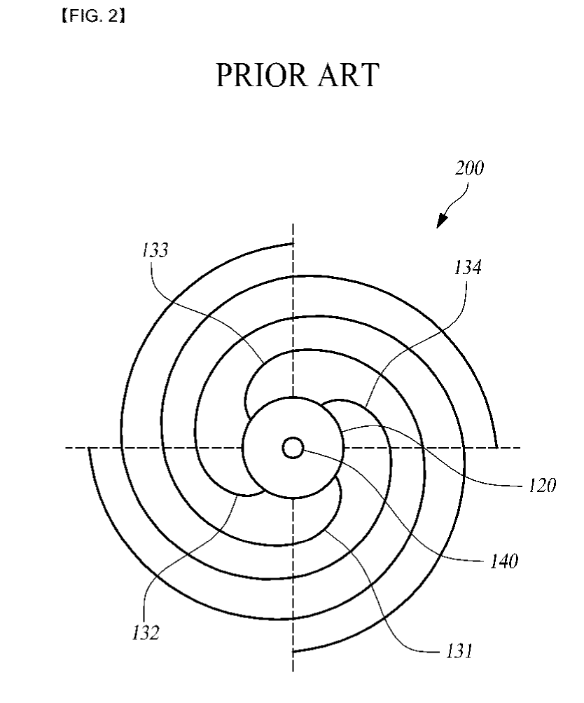

FIG. 3 is a perspective view for showing the construction of hubs in a plasma source according to an aspect of the present disclosure;

FIG. 4 is a plan view for showing the construction of one of main coils in a plasma source according to an aspect of the present disclosure; and

FIGS. 5 and 6 are plan views for showing the assemblies of the main coil in FIG. 4 to one of the hubs in FIG. 3, and of the hubs in FIG. 3 with the main coils as in FIG. 4.

### MODE FOR INVENTION

Hereinafter, aspects of the present disclosure will be described in detail with reference to the accompanying drawings. In the following description, the same elements will be preferably designated by the same reference numerals although they are shown in different drawings. Further, in the following description of the present disclosure, a detailed description of known functions and configurations incorporated herein will be omitted when it may make the subject matter of the present disclosure rather unclear.

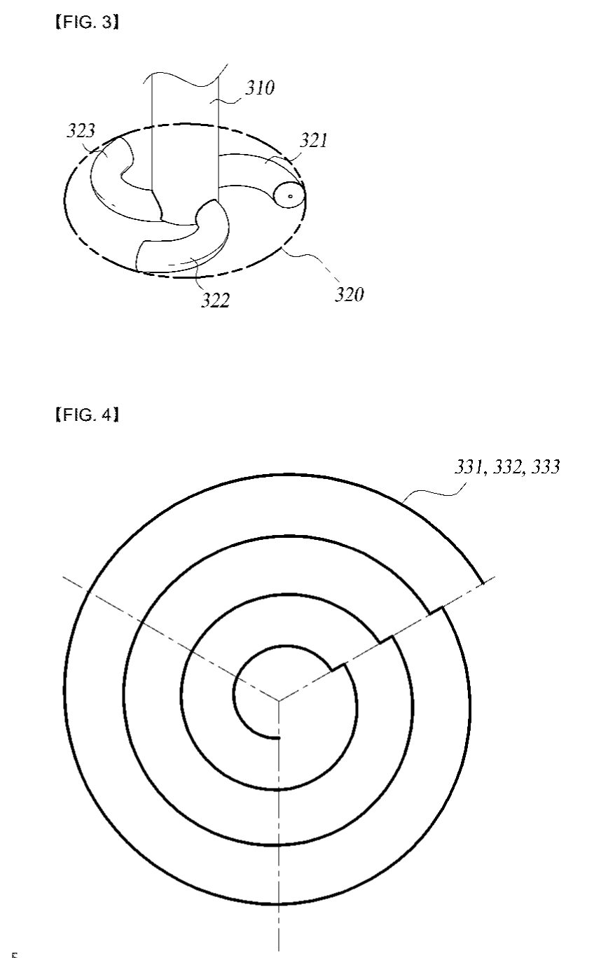

FIG. 3 is a perspective view for showing the construction of hubs in a plasma source according to an aspect of the present disclosure.

As is depicted, hubs 321, 322, 323 stem from a lower end of a conductive disc-shaped core 310 and extend a certain length in a horizontal spiral in a rotationally symmetrical arrangement with respect to each other. In this aspect, the three hubs 321, 322, 323 are illustrated, although the number is not limited and one or more arbitrary number of them may be used to constitute the plasma source. The number of hubs 321, 322, 323 and the diameter of an imaginary circle joining all of the ends of hubs 321, 322, 323 can determine the electrical impedance and electromagnetic properties of the plasma source according to the present disclosure.

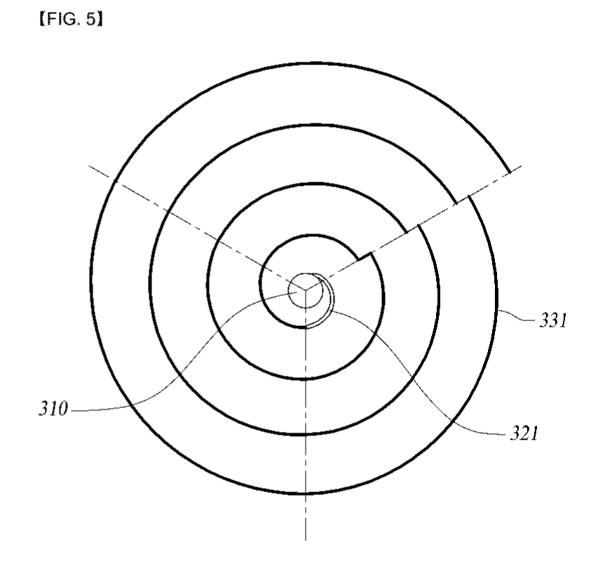

FIG. 4 is a plan view for showing the construction of one of main coils 331, 332, 333 in the plasma source according to an aspect of the present disclosure, wherein there are supposed to be three main coils 331, 332, 333 corresponding to the three hubs 321, 322, 323 but only one is conveniently shown representing the main coils 331, 332, 333.

As is depicted, each of main coils 331, 332, 333, in a continuous extension from an end of each of hubs 321, 322, 323, winds a/m times in a horizontal spiral followed by a certain length of radial extension, winding a/m times in another horizontal spiral followed by a certain length of radial extension, and continues this sequence in multiple repeats, wherein “a” is a positive integer and “m” is the positive integer number of the hubs. In the present aspect, “a” and “m” are both selected to be integer three.

The certain length of radial extension of main coil 331, 332, 333 may be made to become incremental or decremental as the number of turns of the main coil is increased, or it may remain the same regardless of the number of windings of the main coil.

The structure of main coils 331, 332, 333 according to the disclosure plays a significant role in controlling the center plasma density profile. Especially in a HCP (hybridly coupled plasma) source according to the present disclosure, the geometry of hubs 321, 322, 323, the length of radial extension of main coils 331, 332, 333, and the numbers of hubs 321, 322, 323 and main coils 331, 332, 333 will affect the resultant induced magnetic field (B) and the induced electric field (E), which directly influences the plasma density through diffusion.

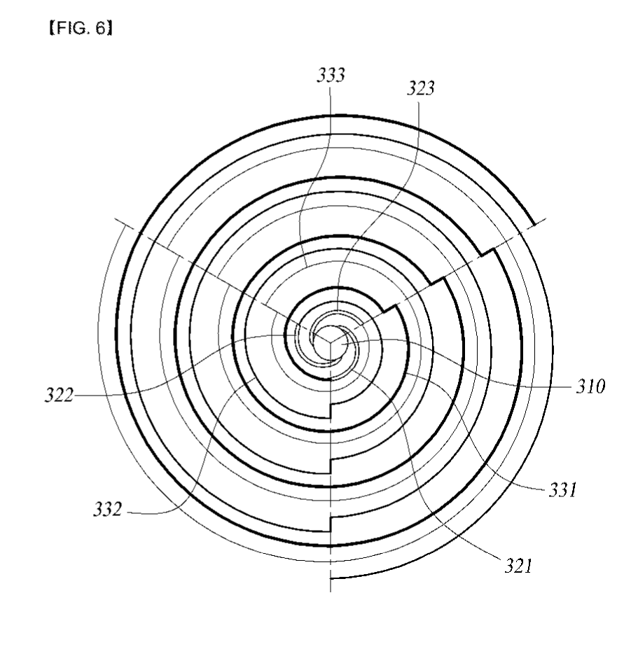

FIG. 5 is a plan view for representing a single assembly of main coil 331 in FIG. 4 to hub 321 in FIG. 3. As is shown in the drawing, hub 321 that stems from the end of core 310 a certain length in a horizontal spiral has main coil 331 extended continuously from the distal end of hub 321 in the horizontal spiral.

FIG. 6 is a plan view for showing the full assembly of the three hubs in FIG. 3 with the three main coils as in FIG. 4. As is shown in the drawing, hubs 321, 322, 323 that stem from the end of core 310 a certain length in horizontal spirals have main coils 331, 332, 333 extended continuously from the distal ends of hubs 321, 322, 323 in the horizontal spirals, respectively.

As is described above, the plasma source according to an aspect presents overall uniform induced magnetic field and the induced electric field for improving the process uniformity, and is able to change the characteristics of the process with variations of the length of radial extension of the coil, spacing between the coils, and the coil counts and turns, etc.

Although exemplary aspects of the present disclosure have been described for illustrative purposes, those skilled in the art will appreciate that various modifications, additions and substitutions are possible, without departing from essential characteristics of the disclosure. Therefore, exemplary aspects of the present disclosure have not been described for limiting purposes.

Accordingly, the scope of the disclosure is not to be limited by the above aspects but by the claims and the equivalents thereof.

### INDUSTRIAL APPLICABILITY

According to the disclosure as described above, when applied to the semiconductor technologies, the disclosed plasma source achieves the symmetrization of the induced magnetic field as well as the induced electric field to improve the process uniformity, and is advantageously capable of changing the characteristics of the process by varying the length of radial extension of the coil, spacing between the coils, and the coil counts and turns.

1. A plasma source arranged at an upper portion of a plasma chamber for forming plasma inside the plasma chamber, the plasma source comprising:
a disc-shaped core;
‘m’ number of hubs, ‘m’ being a positive integer, each hub extending a certain length in a horizontal spiral from the core and the hubs being arranged rotationally symmetrical to each other; and
main coils each, in a continuous extension from an end of each of the hubs, winding a/m times in a horizontal spiral followed by a certain length of radial extension, winding a/m times in another horizontal spiral followed by a certain length of radial extension, and continuing this sequence in multiple repeats, and wherein ‘a’ and ‘m’ are positive integers.

2. The plasma source of claim 1, wherein the certain length of radial extension of the main coil becomes incremental as the number of turns of the main coil increases.

3. The plasma source of claim 1, wherein the certain length of radial extension of the main coil becomes decremental as the number of turns of the main coil increases.

4. The plasma source of claim 1, wherein the certain length of radial extension of the main coil remains the same regardless of the number of turns of the main coil.
